(19) United States
(12) Patent Application Publication
(10) Pub. No.: US 2011/0260762 A1
(43) Pub. Date: Oct. 27, 2011

(54) APPARATUS AND METHOD FOR VCO CALIBRATION USING FAST FREQUENCY COMPARISON BASED ON PHASE MANIPULATION

(75) Inventors: Yun-Young Choi, Seongnam-si (KR); Hoon-Tae Kim, Suwon-si (KR)

(73) Assignee: SAMSUNG ELECTRONICS CO., LTD., Suwon-city, Gyeonggi-do (KR)

(21) Appl. No.: 13/122,294

(22) PCT Filed: Oct. 7, 2009
(86) PCT No.: PCT/KR09/05717

§ 371 Date: Apr. 1, 2011

(30) Foreign Application Priority Data
Oct. 7, 2008 (KR) 10-2008-0098193

(51) Int. Cl. H03L 7/06

(52) U.S. Cl. 327/156

(57) ABSTRACT

An apparatus and a method for calibrating a Voltage Controlled Oscillator (VCO) using a fast frequency comparison based on phase manipulation are provided. The calibrating apparatus includes a phase shifter for comparing an input reference frequency and an input divided frequency and shifting a phase of the reference frequency to make the phase of the reference frequency align with a phase of the divided frequency; a frequency comparator for determining which one of the phase-shifted reference frequency and the divided frequency is higher; and a cap-bank control for determining a frequency to use based on a comparison result of the frequency comparator.

### TECHNICAL FIELD

The present invention relates generally to an apparatus and a method for calibrating an output frequency of a Voltage Controlled Oscillator (VCO) which is one of components of a Phase Locked Loop (PLL) integrated to a Radio Frequency Integrated Circuit (RFIC).

### BACKGROUND ART

To offer various wireless communication services at one terminal, a broadband Voltage Controlled Oscillator (VCO) for covering all frequency bands required by the wireless communication services is necessary.

FIG. 1 is a graph showing a VCO output frequency having multiple bands.

Referring to FIG. 1, the output frequency of the broadband VCO lowers the gain of the VCO by dividing into a plurality of frequency bands #1, #2 and #3 and thus does not deteriorate phase noise characteristics.

Since a general Phase Locked Loop (PLL) structure has no multiband automatic selection function of the VCO, it is necessary to manually set the frequency band of the VCO to change a channel frequency, or to accommodate all the frequency bands with one band by designing the VCO of a high frequency gain. To address those drawbacks, many researches are conducted on a PLL circuit of the automatic calibration capability which automatically selects the operating band of the VCO.

As an example of the research, an automatic band control circuit is implemented around the PLL circuit so as to automatically select the frequency band required by the system without the manual process.

The automatic band control circuit uses two counters to compare two frequencies. The first counter determines the VCO frequency with an N-divided clock, and the second counter determines with a reference clock generating at the crystal. Whether to raise the VCO frequency by selecting the upper band or to lower the frequency by selecting the lower band is determined by comparing the carry-outs of the two counters.

When the crystal reference clock is faster than the divided clock, the carry-out of the second counter is output first and a frequency comparator issues a H signal to raise the frequency.

However, it takes tens to hundreds of us for such a circuit to produce the comparison result of the two frequencies, and the number of the counter bits needs to increase to enhance the comparison accuracy of the two counters. In result, it is hard to apply the circuit to a wireless communication system requiring a short channel switching time.

### DISCLOSURE OF INVENTION

### Solution to Problem

An aspect of the present invention is to address at least the above mentioned problems and/or disadvantages and to provide at least the advantages described below. Accordingly, an aspect of the present invention is to provide an apparatus and a method for calibrating a Voltage Controlled Oscillator (VCO) using a fast frequency comparison based on phase manipulation.

Another aspect of the present invention is to provide an apparatus and a method for calibrating a VCO having an automatic calibration capability which automatically selects an operating band.

Yet another aspect of the present invention is to provide VCO calibrating apparatus and method for drastically reducing a channel switching time by promptly detecting a band of a frequency to synthesize, and enhancing flexibility of a loop filter coefficient selection in a Phase Locked Loop (PLL) design by assigning the reduced time to the PLL design.

According to one aspect of the present invention, an apparatus for calibrating a VCO using a fast frequency comparison based on phase manipulation includes a phase shifter for comparing an input reference frequency and an input divided frequency and shifting a phase of the reference frequency to make the phase of the reference frequency align with a phase of the divided frequency; a frequency comparator for determining which one of the phase-shifted reference frequency and the divided frequency is higher; and a cap-bank control for determining a frequency to use based on a comparison result of the frequency comparator.

According to another aspect of the present invention, a method for calibrating a VCO using a fast frequency comparison based on phase manipulation includes comparing an input reference frequency and an input divided frequency and shifting a phase of the reference frequency to make the phase of the reference frequency align with a phase of the divided frequency; determining which one of the phase-shifted reference frequency and the divided frequency is higher; and determining a frequency to use based on a comparison result.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF DRAWINGS

The above and other aspects, features and advantages of certain exemplary embodiments the present invention will become more apparent from the following detailed description taken in conjunction with the accompanying drawings, in which:

FIG. 1 is a graph of a VCO output frequency having multiple bands;

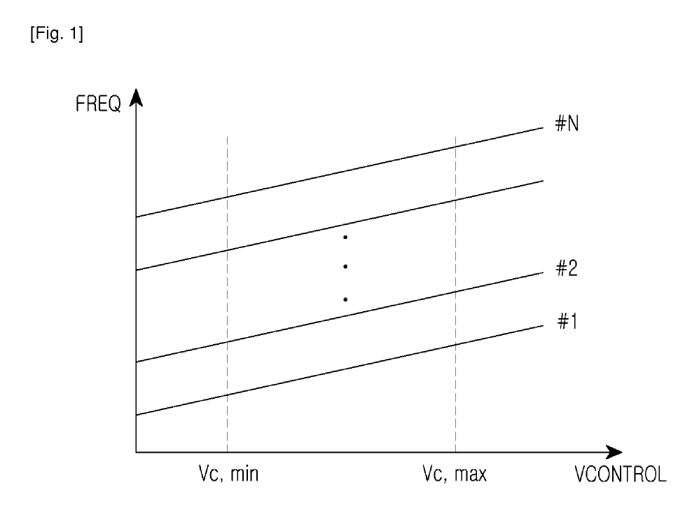

FIG. 2 is a diagram of a PLL structure having a frequency automatic calibration function according to an exemplary embodiment of the present invention;

FIG. 3 is a flowchart of a fast VCO frequency automatic calibration according to an exemplary embodiment of the present invention; and

FIG. 4 is a phase diagram for the fast VCO frequency automatic calibration according to an exemplary embodiment of the present invention.

Throughout the drawings, like reference numerals will be understood to refer to like parts, components and structures.

### BEST MODE FOR CARRYING OUT THE INVENTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein may be made without departing from the scope and spirit of the invention. Also, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide

Exemplary embodiments of the present invention provide an apparatus and a method for calibrating a Voltage Controlled Oscillator (VCO) using fast frequency comparison based on phase manipulation.

The present invention is to automatically set a frequency band of a broadband VCO of multiple bands and to meet a short channel switching time required by a system by means of a fast VCO frequency automatic calibration scheme.

The channel switching time according to a system standard is a sum of a time taken to select the frequency band and a time taken to lock a Phase Locked Loop (PLL). Hence, more time as much as the time reduced by the fast VCO frequency automatic calibration may be allotted to the PLL locking.

When the PLL loop filter is designed, this helps to increase the design flexibility of the loop coefficient selection under less limitation on the PLL locking time.

The present invention provides largely two operations. The first operation is an automatic band selection operation for selecting a band of the intended frequency among the multiple bands of the VCO and the second operation is a PLL operation for locking a necessary frequency using the PLL over the selected band.

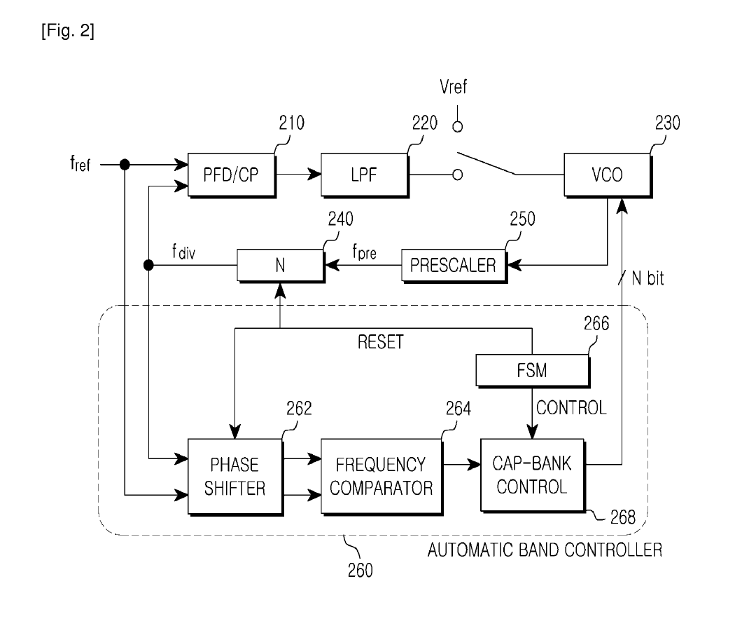

FIG. 2 illustrates a PLL structure having the frequency automatic calibration function according to an exemplary embodiment of the present invention.

The PLL structure of FIG. 2 includes a PLL part including a plurality of function blocks 210, 220, 230, 240 and 250, and an automatic band controller 260. The PLL part represents an integer-N or fractional-N type PLL circuit generally used to synthesize frequencies.

The automatic band controller 260 includes a phase shifter 262, a frequency comparator 264, a cap-bank control 268, and a Final State Machine (FSM) 266.

The phase shifter 262 compares two input frequencies and shifts a phase of a reference frequency so that the phase of the reference frequency is aligned with a divided frequency phase.

The frequency comparator 264 determines which one of the phase-shifted reference frequency and the divided frequency is higher.

The cap-bank control 268 determines whether to select the upper band or the lower band from the multiple bands of the VCO based on the comparison result of the frequency comparator 264, and provides the determination to the VCO 230. The VCO 230 determines the frequency band based on the value (the cap-bank value) fed from the automatic band controller 260.

The FSM 266 provides control signals such as reset or write, required by the phase shifter 262, the frequency comparator 264, and the cap-bank control 268.

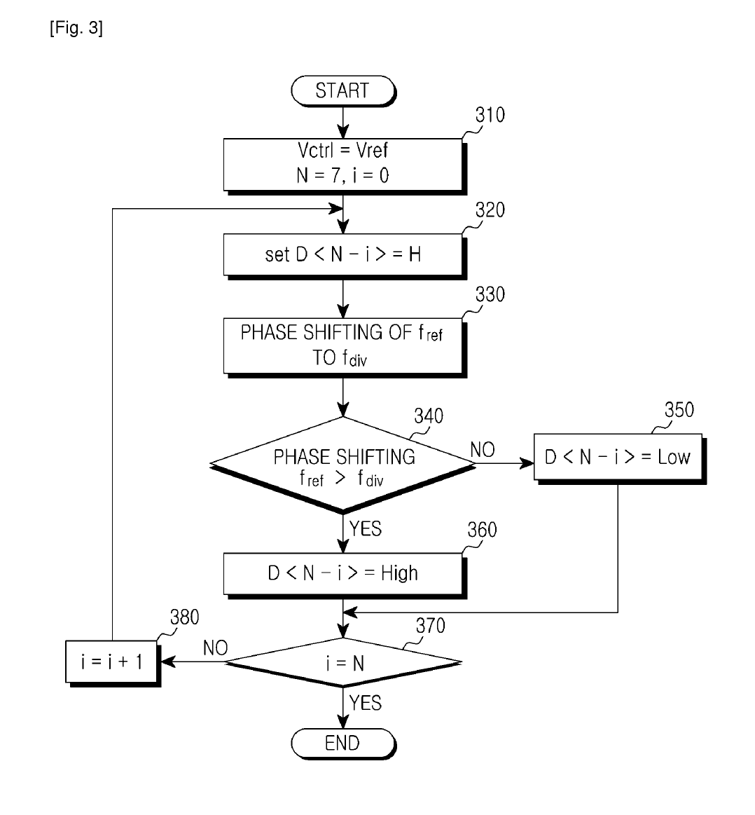

FIG. 3 is a flowchart of a fast VCO frequency automatic calibration according to an exemplary embodiment of the present invention.

Referring to FIG. 3, the automatic band selection operations for selecting the band of the intended frequency from the multiple bands of the VCO are illustrated.

To promptly determine the N-bit cap-bank value, the algorithm used herein reduces the number of the comparisons to N times through the binary search in order starting from a Most Significant Bit (MSB) to a Least Significant Bit (LSB), rather than sequentially searching the number of cases of (2̂N−1)-ary cap-bank values and determining the searched value.

First, for the automatic band control operations, the PLL loop is cut off and the control voltage of the VCO is fixed to Vref (Vctrl=Vref). Other variables for the algorithm operation are initialized (N=7, i=0) in step 310.

Next, D<N−1> corresponding to the MSB of the cap-bank control signals D<0>, D<1>, . . . , D<N−1> of the VCO is set to ‘H’ in step 320, the rising edge of the reference frequency fref is shifted to align with the rising edge of the divided frequency fdiv in step 330, and the two frequencies are compared in step 340.

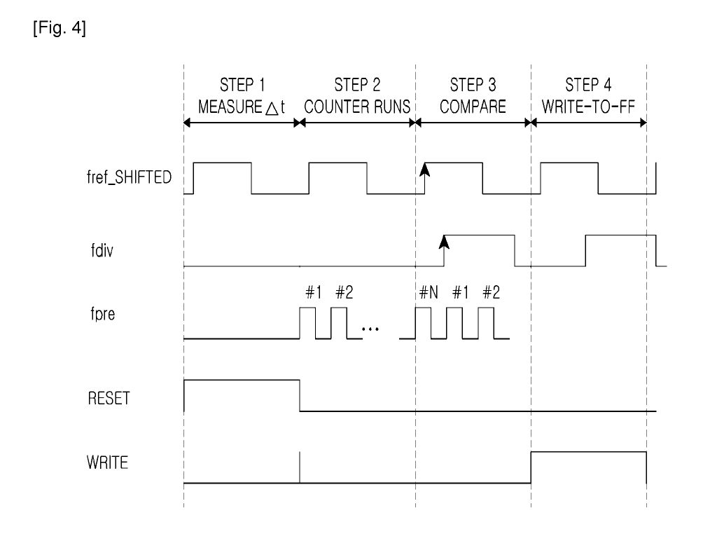

Herein, the shift operation is carried out by the phase shifter 262 of FIG. 2. The two frequencies are compared by the frequency comparator 264 of FIG. 2. The alignment of rising edges of the two frequencies shall be described in FIG. 4.

When the phase-shifted reference frequency fref is higher in step 340, D<N−1> sustains ‘H’ (High) in step 360. When the divided frequency fdiv is higher, D<N−1> is changed to ‘L’ (Low) in step 350.

When the cap-bank value for the MSB is determined as above, the cap-bank value for D<N−2> of the next weighting value is determined in the same manner and this process is repeated until the cap-bank value for D<0> corresponding to the LSB is determined in steps 320 through 380.

To repeat those operations, the present algorithm increases the variable (i) value by one in the unit of the bit and finishes when the operations are completed up to the intended bit (i=N).

The cap-bank values determined as above are stored to the D-Flip-Flop (FF) and sustained even when the fast VCO frequency automatic calibration loop ends.

Next, after the fast VCO frequency automatic calibration operation ends, the VCO 230 linked to the Vref is switched to the LPF 220 of the PLL part to drive the PLL loop.

Next, the cap-bank control 268 outputs the cap-bank value stored to the D-FF according to the two input frequencies. This value is input to the VCO 230 to make the VCO 230 select the intended frequency band.

Next, the algorithm of the present invention is finished.

FIG. 4 is a phase diagram for the fast VCO frequency automatic calibration according to an exemplary embodiment of the present invention.

Referring to FIG. 4, fref shifted is the frequency after being shifted to make the rising edge of the reference frequency align with the rising edge of the divided edge, and fdiv is the N-divided frequency of the fpre frequency.

The Reset signal is originated from the FSM 266 of FIG. 2 and resets the N divider 240 and the phase shifter 262. The Write signal writes the comparison result of fred_shifted and fdiv to the D-FF.

It takes 4 cycles to compare fred_shifted and fdiv once, which includes four steps as below:

Step 1. Measure the phase difference Δt of fref and fdiv and shift fref by Δt.

Step 2. Run the N divider counter.

Step 3. Compare the rising edge of fref_shifted with the rising edge of fdiv.

Step 4. Write the frequency comparison result to the D-Flip-Flip (FF).

Even when the phase difference is measured and the fref is shifted by the phase difference in Step 1, the phase alignment is not accurate. The accurate phase alignment is achieved through Step 2 and Step 3. Step 4 corresponds to step 350 or step 360 of FIG. 3.

In general, while it takes Tref * 2̂ (# of counter bits) to determine one bit of the N-bit cap-bank control signal (for example, when the 8-bit counter runs at the reference frequency 20 Mhz, it takes 50 ns * 2̂8=12.8 us), the frequency comparison time of the present invention requires merely 200 ns in the Tref * 4 cycle to thus drastically reduce the channel switching time.

The fast VCO frequency automatic calibration scheme of the present invention may not only remarkably reduce the channel switching time by promptly searching the band of the frequency to synthesize but also enhance the flexibility of the loop filter coefficient selection in the PLL design by allotting the time reduced by the fast algorithm to the PLL design.

While the invention has been shown and described with reference to certain exemplary embodiments thereof, it will be understood by those skilled in the art that various changes in form and details may be made therein without departing from the spirit and scope of the invention as defined by the appended claims and their equivalents.

1. An apparatus for calibrating a Voltage Controlled Oscillator (VCO) using a fast frequency comparison based on phase manipulation, the apparatus comprising:
a phase shifter for comparing an input reference frequency and an input divided frequency and shifting a phase of the reference frequency to make the phase of the reference frequency align with a phase of the divided frequency;
a frequency comparator for determining which one of the phase-shifted reference frequency and the divided frequency is higher; and
a cap-bank control for determining a frequency to use based on a comparison result of the frequency comparator.

2. The apparatus of claim 1, wherein the phase shifter aligns a rising edge of the reference frequency with a rising edge of the divided frequency until cap-bank values corresponding to a Most Significant Bit (MSB) and a Least Significant Bit (LSB) of a cap-bank control signal for the VCO are determined.

3. The apparatus of claim 2, wherein the phase shifter aligns the rising edge of the reference frequency with the rising edge of the divided frequency by measuring a difference of the reference frequency and the divided frequency, shifting the reference frequency by the difference, and comparing the rising edge of the shifted reference frequency and the rising edge of the divided frequency using a N divider counter.

4. The apparatus of claim 2, wherein the frequency comparator determines which one of the aligned reference frequency and the divided frequency is higher.

5. The apparatus of claim 4, wherein the cap-bank control determines the cap-bank values from the MSB bit to the LSB bit by taking into account the comparison result of the aligned reference frequency and the divided frequency.

6. A method for calibrating a Voltage Controlled Oscillator (VCO) using a fast frequency comparison based on phase manipulation, the method comprising:
comparing an input reference frequency and an input divided frequency and shifting a phase of the reference frequency to make the phase of the reference frequency align with a phase of the divided frequency;
determining which one of the phase-shifted reference frequency and the divided frequency is higher; and
determining a frequency to use based on a comparison result.

7. The method of claim 6, wherein the comparing of the input reference frequency and the input divided frequency and the shifting of the phase of the reference frequency to make the phase of the reference frequency align with the phase of the divided frequency comprises:
aligning a rising edge of the reference frequency with a rising edge of the divided frequency until cap-bank values corresponding to a Most Significant Bit (MSB) and a Least Significant Bit (LSB) of a cap-bank control signal for the VCO are determined.

8. The method of claim 7, wherein the aligning of the rising edge of the reference frequency with the rising edge of the divided frequency comprises:
measuring a difference of the reference frequency and the divided frequency;
shifting the reference frequency by the difference; and
aligning the rising edge of the reference frequency with the rising edge of the divided frequency by comparing the rising edge of the shifted reference frequency and the rising edge of the divided frequency using a N divider counter.

9. The method of claim 7, wherein the determining of which one of the phase-shifted reference frequency and the divided frequency is higher comprises:
determining which frequency is higher by comparing the aligned reference frequency and the divided frequency.

10. The method of claim 9, wherein the determining of the frequency to use based on the comparison result comprises:
determining the cap-bank values from the MSB bit to the LSB bit by taking into account the comparison result of the aligned reference frequency and the divided frequency.
